(19) United States
(12) Patent Application Publication
(10) Pub. No.: US 2025/0226242 A1
(43) Pub. Date: Jul. 10, 2025

(54) METHOD OF PROCESSING WAFER

(71) Applicant: DISCO CORPORATION, Tokyo (JP)

(72) Inventors: Akira MIZUTANI, Tokyo (JP); Honoka ARAI, Tokyo (JP); Yutaka KOBAYASHI, Tokyo (JP); Masahiro TSUKAMOTO, Tokyo (JP)

(21) Appl. No.: 18/975,059

(22) Filed: Dec. 10, 2024

(30) Foreign Application Priority Data
Jan. 10, 2024 (JP) 2024-001765

(51) Int. Cl. H01L 21/67; B23K 26/53; H01L 21/02; H01L 21/304; H01L 21/78

(52) U.S. Cl. CPC H01L 21/67092; B23K 26/53; H01L 21/02021; H01L 21/304; H01L 21/78

(57) ABSTRACT

A method of processing a wafer having a first wafer bonded to a second wafer includes a modified layer forming step of applying a laser beam to the first wafer while positioning a focused spot of the laser beam within the first wafer radially inwardly of and adjacent to a chamfered outer circumferential edge of the first wafer, to form a ring-shaped modified layer in the first wafer, a chamfered outer circumferential edge removal promoting step of supplying an interface between the first wafer and the second wafer near the chamfered outer circumferential edge with fluid for reducing a bonding force of the interface and sending the fluid into a region of the interface for removing the chamfered outer circumferential edge, and a chamfered outer circumferential edge removing step of removing the chamfered outer circumferential edge from the first wafer along the modified layer as a removal initiating point.

### BACKGROUND OF THE INVENTION

### Field of the Invention

The present invention relates to a method of processing a wafer that is bonded as a first wafer to a second wafer in a bonded wafer assembly.

### Description of the Related Art

Wafers having a plurality of devices such as integrated circuits (ICs) or large-scale integration (LSI) circuits, for example, constructed in respective areas demarcated on their face side by a grid of projected dicing lines are ground on their reverse side to a predetermined thickness. Thereafter, the wafers are divided into individual device chips including the respective devices along the projected dicing lines by a dicing apparatus or a laser processing apparatus. The device chips will be incorporated in various electronic appliances such as cellular phones and personal computers, for example.

Each of the wafers has a chamfered outer circumferential edge. When the reverse side of the wafer is ground, the chamfered outer circumferential edge is turned into a sharp knife edge that is likely to cause various problems. For example, the knife edge tends to develop cracks into the wafer, damaging some of the devices positioned in a central region of the wafer, and is liable to inflict injuries on an operator when the operator handles the wafer. To solve these problems, there has been proposed a technology for removing the chamfered outer circumferential edge from a wafer (see, for example, JP 2020-088187A).

### SUMMARY OF THE INVENTION

However, the proposed technology finds it relatively difficult to remove the chamfered outer circumferential edge from a wafer in a bonded wafer assembly including a first wafer and a second wafer that are bonded to each other for increased device functionality, the first wafer being the wafer from which the chamfered outer circumferential edge is to be removed. The reasons for the difficulty will be described below.

(1) The bonding strength or force of the bonded wafer assembly in which the first wafer and the second wafer are bonded to each other by a siloxane bond is so strong that it is difficult to remove the chamfered outer circumferential edge from the first wafer even if a modified layer is formed in the first wafer by a laser beam having a wavelength transmittable through the first wafer when the laser beam is applied to the first wafer while its focused spot is positioned within the first wafer adjacent to the chamfered outer circumferential edge.

(2) When the modified layer is formed in the first wafer for the removal of the chamfered outer circumferential edge from the first wafer while the first wafer and the second wafer is being held in intimate contact with each other, the laser beam applied to the first wafer to form the modified layer therein is liable to adversely affect the second wafer to the extent that the second wafer may possibly be damaged.

(3) One alternative is to use a cutting blade to cut off the chamfered outer circumferential edge from the first wafer. However, it is difficult for the cutting blade to completely remove the chamfered outer circumferential edge from the first wafer without harming the first wafer.

It is an object of the present invention to provide a method of processing a wafer that is bonded as a first wafer to a second wafer in a bonded wafer assembly, to appropriately remove a chamfered outer circumferential edge from the first wafer.

In accordance with an aspect of the present invention, there is provided a method of processing a wafer that is bonded as a first wafer to a second wafer in a bonded wafer assembly, including a modified layer forming step of applying a laser beam to the first wafer while positioning a focused spot of the laser beam within the first wafer radially inwardly of and adjacent to a chamfered outer circumferential edge of the first wafer, to form a ring-shaped modified layer in the first wafer, a chamfered outer circumferential edge removal promoting step of supplying an interface between the first wafer and the second wafer that are bonded to each other near the chamfered outer circumferential edge with fluid for reducing a bonding force of the interface and sending the fluid into a region of the interface for removing the chamfered outer circumferential edge, and after the chamfered outer circumferential edge removal promoting step, a chamfered outer circumferential edge removing step of removing the chamfered outer circumferential edge from the first wafer along the modified layer as a removal initiating point.

Preferably, the method of processing a wafer further includes an external force imparting step of imparting an external force to the interface. The chamfered outer circumferential edge removal promoting step includes reducing the bonding force of the interface with the fluid in combination with the external force. Preferably, the modified layer forming step includes a first step of applying the laser beam to the first wafer while positioning the focused spot thereof in a vicinity of the interface, to form a relatively deep first modified layer in the first wafer with cracks therealong reaching the interface, and a second step of forming a relatively shallow second modified layer that is disposed radially inwardly or outwardly of and adjacent to the first modified layer and that does not reach the interface. The second step is carried out to impart an external force for buckling the chamfered outer circumferential edge away from the interface along the first modified layer as a buckling initiating point.

Preferably, the modified layer forming step includes forming a plurality of radial modified layers in the first wafer, the plurality of radial modified layers extending radially outwardly from the ring-shaped modified layer. The chamfered outer circumferential edge removal promoting step may be carried out before the modified layer forming step, after the modified layer forming step, or simultaneously with the modified layer forming step. Preferably, the method of processing a wafer further includes, after the chamfered outer circumferential edge removing step, a grinding step of grinding an upper surface of the first wafer to thin down the first water.

Preferably, the first wafer and the second wafer are bonded to each other by a siloxane bond represented by an Si—O—Si bond, and the fluid for reducing the bonding force includes either water, water vapor, or water mist, and the chamfered outer circumferential edge removal promoting step includes reducing the bonding force of the interface by changing the Si—O—Si bond to an Si—OH—OH—Si bond.

The method of processing a wafer according to the aspect of the present invention is able to appropriately remove the chamfered outer circumferential edge from the first wafer in processing the first wafer that is joined to the second wafer in the bonded wafer assembly.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is an exploded perspective view of a bonded wafer assembly to be processed by a method of processing a wafer according to an embodiment of the present invention;

FIG. 2 is a perspective view of a laser processing apparatus that is used to carry out the method of processing a wafer;

FIG. 3 is a perspective view illustrating the manner in which the bonded wafer assembly is held on a chuck table of the laser processing apparatus illustrated in FIG. 2;

FIG. 4 is an enlarged fragmentary side elevational view illustrating the manner in which a chamfered outer circumferential edge removal promoting step of the method of processing a wafer is carried out;

FIG. 5 is a perspective view illustrating the manner in which a modified layer forming step of the method of processing a wafer is carried out;

FIG. 6A is an enlarged fragmentary side elevational view illustrating the manner in which a first step of the modified layer forming step is carried out;

FIG. 6B is an enlarged fragmentary side elevational view illustrating the manner in which a second step of the modified layer forming step is carried out;

FIG. 7 is a plan view of the first wafer that includes radial modified layers formed therein;

FIG. 8 is a perspective view illustrating the manner in which a chamfered outer circumferential edge removing step of the method of processing a wafer is carried out;

FIG. 9A is an enlarged fragmentary side elevational view illustrating the manner in which a chamfered outer circumferential edge removal promoting step according to a first modification is carried out;

FIG. 9B is an enlarged fragmentary side elevational view illustrating the manner in which a chamfered outer circumferential edge removal promoting step according to a second modification is carried out;

FIG. 9C is an enlarged fragmentary side elevational view illustrating the manner in which a chamfered outer circumferential edge removal promoting step and an external force imparting step according to a third modification are simultaneously carried out;

FIG. 9D is an enlarged fragmentary side elevational view illustrating the manner in which a chamfered outer circumferential edge removal promoting step and an external force imparting step according to a fourth modification are simultaneously carried out; and

FIG. 10 is a perspective view illustrating the manner in which a grinding step of the method of processing a wafer is carried out.

### DETAILED DESCRIPTION OF THE PREFERRED EMBODIMENT

A method of processing a wafer according to an embodiment of the present invention and various modifications thereof will be described in detail below with reference to the accompanying drawings.

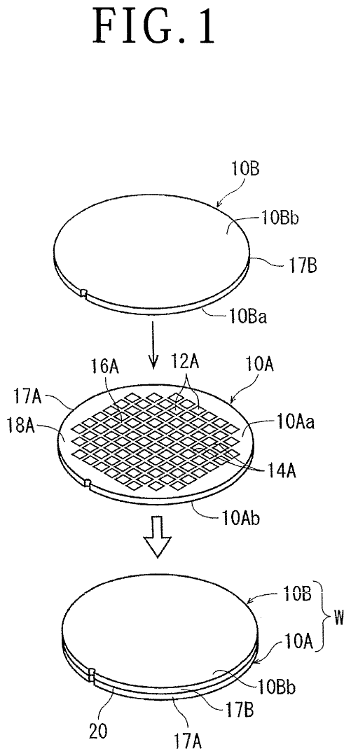

FIG. 1 illustrates in perspective a bonded wafer assembly W as an example of workpiece to be processed by the method of processing a wafer according to the present embodiment. As illustrated in FIG. 1, the bonded wafer assembly W includes a first wafer 10A and a second wafer 10B that are integrally bonded to each other. The first wafer 10A is a wafer of silicon (Si) having a diameter of 300 mm and a thickness of 300 μm, for example. A plurality of devices 12A are constructed in respective areas demarcated on a face side 10Aa of the first wafer 10A by a grid of projected dicing lines 14A established thereon. The first wafer 10A has a reverse side 10Ab facing downwardly in FIG. 1 that is opposite the face side 10Aa facing upwardly in FIG. 1. The first wafer 10A includes a central effective region 16A where the devices 12A are provided for use as individual products and an outer circumferential excess region 18A surrounding the central effective region 16A. The outer circumferential excess region 18A has a chamfered outer circumferential edge 17A. The second wafer 10B is also a wafer of silicon and is similar in structure to the first wafer 10A. The second wafer 10B also includes a chamfered outer circumferential edge 17B. Although not illustrated, the second wafer 10B has a central effective region where a plurality of devices are constructed in respective areas demarcated on a face side 10Ba facing downwardly in FIG. 1.

The first wafer 10A and the second wafer 10B are integrally combined with each other such that the face side 10Aa of the first wafer 10A and the face side 10Ba of the second wafer 10B are bonded to each other by a siloxane bond, providing an interface 20 therebetween. The siloxane bond refers to an Si—O—Si bond where silicon (Si) and oxygen (O) atoms are alternately bonded to each other. Since the first wafer 10A and the second wafer 10B are bonded to each other in heat treatment, they remain firmly bonded even at high temperatures.

The method of processing a wafer according to the present embodiment is performed on the first wafer 10A of the bonded wafer assembly W, and includes a modified layer forming step of forming a ring-shaped modified layer in the first wafer 10A with a laser beam that is applied to the first wafer 10A and has a focused spot positioned in the first wafer 10A adjacent to the chamfered outer circumferential edge 17A of the first wafer 10A and a chamfered outer circumferential edge removal promoting step of supplying fluid, e.g., pure water, for reducing the bonding force to the interface 20 in the vicinity of the chamfered outer circumferential edge 17A of the first wafer 10A and the chamfered outer circumferential edge 17B of the second wafer 10B and introducing the fluid into a region of the first wafer 10A where the chamfered outer circumferential edge 17A can be removed.

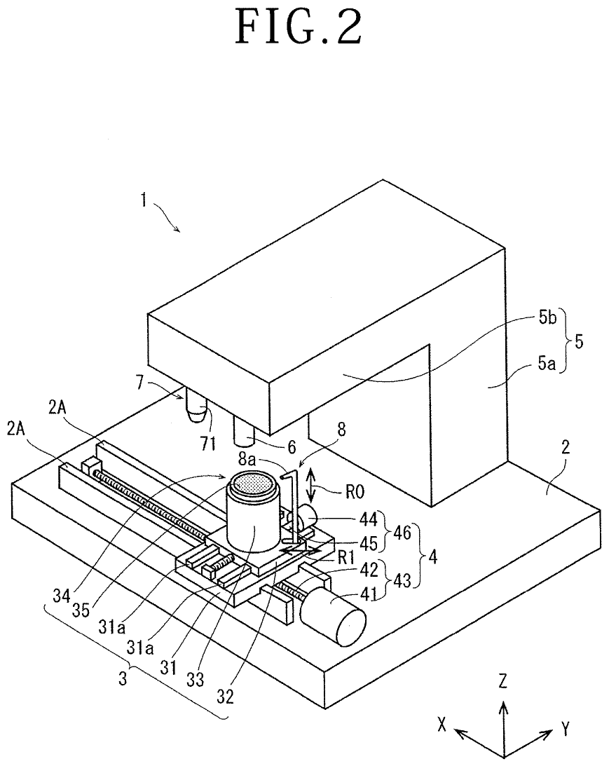

FIG. 2 illustrates in perspective a laser processing apparatus 1 configured to perform the modified layer forming step and the chamfered outer circumferential edge removal promoting step according to the present embodiment. The laser processing apparatus 1 is illustrated in reference to a three-dimensional XYZ coordinate system having an X-axis represented by an arrow X, a Y-axis represented by an arrow Y, and a Z-axis represented by an arrow Z in FIG. 1. The X-axis and the Y-axis extend horizontally and perpendicularly to each other, and the Z-axis extends vertically and perpendicularly to the X-axis and the Y-axis.

As illustrated in FIG. 2, the laser processing apparatus 1 includes a holding unit 3 that is disposed on a base 2 and that holds the bonded wafer assembly W thereon, a moving mechanism 4 for moving the holding unit 3, an alignment unit 6 for capturing an image of the bonded wafer assembly W on the holding unit 3 and carrying out a positioning step on the bonded wafer assembly W on the basis of the captured image, a laser beam applying unit 7 for applying a laser beam to the bonded wafer assembly W on the holding unit 3, a frame 5 including a vertical wall 5a elected on the base 2 sideways of the moving mechanism 4 and a horizontal beam 5b extending horizontally from an upper end portion of the vertical wall 5a in overhanging relation to the holding unit 3, and a fluid supply unit 8 for supplying fluid to the bonded wafer assembly W on the holding unit 3.

The holding unit 3 includes a rectangular X-axis movable plate 31 movably mounted on the base 2 for movement along the X-axis, a rectangular Y-axis movable plate 32 movably mounted on the X-axis movable plate 31 for movement along the Y-axis, a hollow cylindrical post 33 fixedly mounted on an upper surface of the Y-axis movable plate 32, and a chuck table 34 disposed on an upper distal end of the post 33. The chuck table 34 is rotatable about a vertical central axis parallel to the Z-axis by an unillustrated rotating mechanism housed in the post 33. The chuck table 34 has an upper holding surface for holding the bonded wafer assembly W thereon. The upper holding surface of the chuck table 34 is provided by an upper surface of a suction chuck 35 made of an air-permeable porous material. The suction chuck 35 is fluidly connected to unillustrated suction means through an unillustrated fluid channel extending vertically through the post 33. When the suction means is actuated, it generates and transmits a negative pressure through the fluid channel to the upper surface of the suction chuck 35 for holding the bonded wafer assembly W under suction thereon.

The moving mechanism 4 includes an X-axis moving mechanism 43 for moving the holding unit 3 along the X-axis and a Y-axis moving mechanism 46 for moving the holding unit 3 along the Y-axis that is perpendicular to the X-axis. The X-axis moving mechanism 43 converts rotary motion of an electric motor 41 into linear motion and transmits the linear motion to the X-axis movable plate 31 with a ball screw 42, moving the X-axis movable plate 31 along the X-axis on and along a pair of guide rails 2A that are mounted on the base 2 and extend along the X-axis. The Y-axis moving mechanism 46 converts rotary motion of an electric motor 44 into linear motion and transmits the linear motion to the Y-axis movable plate 32 with a ball screw 45, moving the Y-axis movable plate 32 along the Y-axis on and along a pair of guide rails 31a that are mounted on the X-axis movable plate 31 and extend along the Y-axis.

The horizontal beam 5b of the frame 5 houses therein unillustrated part of an optical system of the laser beam applying unit 7. The optical system of the laser beam applying unit 7 also includes a beam condenser 71 mounted on a lower surface of a distal end portion of the horizontal beam 5b. The beam condenser 71 focuses a laser beam that is emitted by an unillustrated light source of the laser beam applying unit 7 and that has a wavelength transmittable through at least the first wafer 10A of the bonded wafer assembly W. The beam condenser 71 applies the laser beam to the bonded wafer assembly W on the chuck table 34 while positioning the focused spot of the laser beam within the first wafer 10A. The alignment unit 6 is disposed on the lower surface of the distal end portion of the horizontal beam 5b at a position adjacent to the beam condenser 71 along the X-axis. The alignment unit 6 includes unillustrated image capturing means that captures an image of the bonded wafer assembly W on the holding unit 3. The alignment unit 6 detects the position and orientation of the bonded wafer assembly W and a processing position where the laser beam is to be applied to the bonded wafer assembly W on the basis of the captured image.

The fluid supply unit 8 is disposed on the Y-axis movable plate 32 adjacent to the chuck table 34. The fluid supply unit 8 has a nozzle 8a on its upper distal end and is fluidly connected to an unillustrated fluid supply source that supplies the fluid to the nozzle 8a. The fluid supply unit 8 is movable by unillustrated drive means in vertical directions indicated by an arrow R0 and horizontal directions indicated by an arrow R1 toward and away from the center of the chuck table 34 to position the nozzle 8a in a desired location for ejecting the fluid, denoted by L in FIG. 4, from its tip end.

The laser processing apparatus 1 further includes, in addition to the above components, an unillustrated controller for controlling them and an unillustrated display unit for displaying various pieces of information. The controller, which includes a computer, includes a central processing unit (CPU) for performing arithmetic processing operations according to control programs, a read only memory (ROM) for storing the control programs and other data, a random access memory (RAM) for temporarily storing detected values and results of the arithmetic processing operations, an input interface, and an output interface. Details of these components of the controller are omitted from illustration as they are well known in the art. The moving mechanism 4, the alignment unit 6, the laser beam applying unit 7, and the display unit are electrically connected to the controller.

The laser processing apparatus 1 according to the present embodiment is of the construction as described above. According to the present embodiment, the method of processing a wafer further includes a chamfered outer circumferential edge removing step to be described later. Prior to the chamfered outer circumferential edge removing step, the modified layer forming step and the chamfered outer circumferential edge removal promoting step of the method of processing a wafer according to the present embodiment will be described below.

The modified layer forming step can be carried out by the laser processing apparatus 1. The chamfered outer circumferential edge removal promoting step can be carried out by the laser processing apparatus 1 before the modified layer forming step, after the modified layer forming step, or simultaneously with the modified layer forming step. According to the present embodiment, the chamfered outer circumferential edge removal promoting step is carried out before the modified layer forming step. The chamfered outer circumferential edge removal promoting step can carried out by the laser processing apparatus 1 using the fluid supply unit 8 thereof.

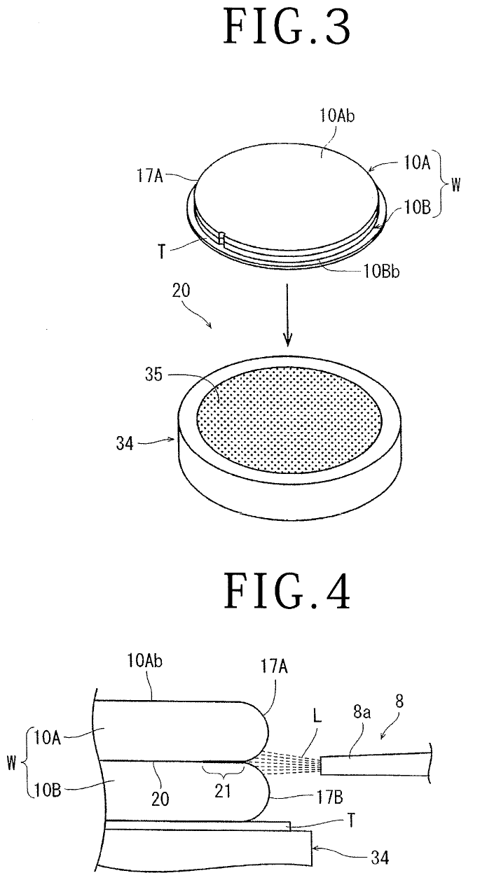

After the bonded wafer assembly W described above with reference to FIG. 1 has been prepared, the bonded wafer assembly W is delivered to the laser processing apparatus 1 described above with reference to FIG. 2. Then, the bonded wafer assembly W is placed on the suction chuck 35 that provides the holding surface of the chuck table 34, with the reverse side 10Ab of the first wafer 10A facing upwardly and the second wafer 10B facing downwardly. According to the present embodiment, a protective tape T is affixed to a reverse side 10Bb, opposite the face side 10Ba, of the second wafer 10B in order to prevent the fluid L supplied in the chamfered outer circumferential edge removal promoting step from being drawn into the suction chuck 35 by the negative pressure acting on the holding surface of the chuck table 34. The protective tape T illustrated in FIG. 3 is slightly larger in diameter than the suction chuck 35 such that the protective tape T covers at least the suction chuck 35 in its entirety. In a case where the fluid L drawn into the suction chuck 35 by the negative pressure causes no problem, the protective tape T may be omitted.

Once the bonded wafer assembly W has been placed on the chuck table 34, the suction means is actuated to hold the bonded wafer assembly W under suction on the chuck table 34. Then, the fluid supply unit 8 is moved in selected ones of the directions indicated by the arrows R0 and R1 in FIG. 2 until the tip end of the nozzle 8a is positioned vertically at the height of the interface 20 between the first wafer 10A and the second wafer 10B that are bonded together and horizontally close to a lateral edge of the interface 20.

Next, the fluid supply source supplies the fluid L for reducing the bonding force of the interface 20 to the nozzle 8a, which ejects the fluid L as a liquid from its tip end toward the interface 20, while, at the same time, the chuck table 34 is rotated about its vertical central axis. As described above, the first wafer 10A and the second wafer 10B are bonded together across the interface 20 provided by the siloxane bond (Si—O—Si bond). The fluid L, e.g., pure water, applied laterally to the interface 20 sends water molecules gradually into a region of the interface 20 where the Si—O—Si bond changes into an Si—OH—OH—Si bond. The bonding force of the region of the interface 20 is thus reduced, providing a ring-shaped bonding-force-reduced region 21 (see FIG. 4) in an outer circumferential portion of the interface 20. The fluid L from the nozzle 8a may not be ejected in a liquid form, and may be ejected as vapor or mist.

According to the present embodiment, the fluid L is ejected under high pressure from the nozzle 8a of the fluid supply unit 8. The pressure of the ejected fluid L acts as an external force for buckling the chamfered outer circumferential edge 17A of the first wafer 10A from the interface 20, i.e., the chamfered outer circumferential edge 17B of the second wafer 10B. In other words, the fluid supply unit 8 also functions as external force imparting means for imparting an external force for reducing the bonding force of the interface 20. Accordingly, an external force imparting step of imparting an external force for reducing the bonding force of the interface 20 is carried out at the same time as the chamfered outer circumferential edge removal promoting step. The change in the bonding mechanism of the interface 20 and the external force applied by the ejected fluid L are combined with each other in lowering the intimate contact between the first wafer 10A and the second wafer 10B in the bonding-force-reduced region 21, resulting in the formation of minuscule gaps in the bonding-force-reduced region 21. The bonding-force-reduced region 21 in the outer circumferential portion of the interface 20 is formed out of the central effective region 16A and has its width adjusted by setting the rate at which the fluid L is supplied, the pressure under which the fluid L is ejected, and the speed at which the chuck table 34 is rotated about its vertical central axis to appropriate values.

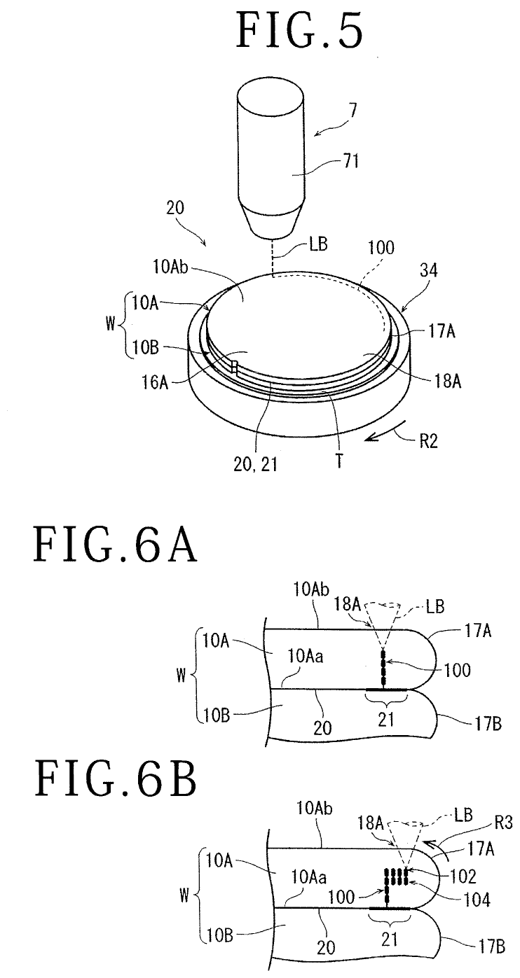

After the chamfered outer circumferential edge removal promoting step has been carried out, the modified layer forming step is carried out as follows. In the modified layer forming step, an alignment process is performed on the bonded wafer assembly W on the chuck table 34 with use of the alignment unit 6 of the laser processing apparatus 1. The alignment process detects the position of the chamfered outer circumferential edge 17A of the first wafer 10A, the position of the center of the first wafer 10A, the height of an upper surface, i.e., the reverse side 10Ab, of the first wafer 10A, and the processing position, e.g., the position at a radius of 147 mm from the center of the first wafer 10A, where the laser beam, denoted by LB in FIG. 5, is to be applied to the first wafer 10A while the focused spot of the laser beam LB is being positioned in the first wafer 10A radially inwardly of and adjacent to the chamfered outer circumferential edge 17A.

The modified layer forming step according to the present embodiment includes a first step and a second step to be described below.

### First Step

On the basis of information regarding the detected processing position, the chuck table 34 is moved to position the processing position set on the first wafer 10A of the bonded wafer assembly W directly below the beam condenser 71 of the laser beam applying unit 7, as illustrated in FIG. 5. Then, as illustrated in FIG. 6A as well as FIG. 5, the laser beam LB is applied from the beam condenser 71 to the reverse side 10Ab of the first wafer 10A while its focused spot is being positioned in the first wafer 10A beneath the processing position, and at the same time, the chuck table 34 is rotated about its vertical central axis in a direction indicated by an arrow R2, thereby forming a ring-shaped first modified layer 100 in the first wafer 10A radially inwardly of and along the chamfered outer circumferential edge 17A of the first wafer 10A.

The first modified layer 100 formed in the first step should preferably be made up of a vertical array of constituent layers, as illustrated in FIG. 6A. For example, the first modified layer 100 illustrated in FIG. 6A is made up of a vertical array of four constituent layers. For forming the first modified layer 100 made up of such a vertical array of four layers, first, the laser beam LB is applied to the first wafer 10A while its focused spot is being positioned in the first wafer 10A at a deepest area close to the interface 20, e.g., at a depth of 180 μm from the reverse side 10Ab, radially inwardly of and adjacent to the chamfered outer circumferential edge 17A, and at the same time, the chuck table 34 is rotated about its vertical central axis, thereby forming a ring-shaped constituent modified layer along the chamfered outer circumferential edge 17A. Thereafter, while the chuck table 34 is being rotated about its vertical central axis, the focused spot of the laser beam LB is lifted successively in three steps toward the reverse side 10Ab, e.g., from the depth of 180 μm to a depth of 170 μm, then from the depth of 170 μm to a depth of 160 μm, and finally from the depth of 160 μm to a depth of 150 μm, during which time the focused spot is kept at each of the depths until the chuck table 34 makes at least one revolution about its vertical central axis. As a result, a total of four ring-shaped constituent modified layers are formed in the first wafer 10A adjacent to and along the chamfered outer circumferential edge 17A.

By thus forming the first modified layer 100 relatively deeply in the first wafer 10A with the laser beam LB that is applied to the first wafer 10A while the focused spot of the laser beam LB is being positioned in the first wafer 10A in the vicinity of the interface 20, cracks are formed in the first wafer 10A along the first modified layer 100 toward the face side 10Aa, i.e., at a relatively deep position reaching the interface 20. In FIG. 6A, the first modified layer 100 is conceptually illustrated for illustrative purposes, and the depthwise positions of its four layers are not in accord with their actual dimensions. The first step is now completed. The constituent layers of the first modified layer 100 formed in the first step is not limited to four layers. The number of constituent layers of the first modified layer 100 is selected depending on the wavelength and power output of the laser beam LB applied to the first wafer 10A by the laser beam applying unit 7, the thickness of the first wafer 10A, and the material of the first wafer 10A among others.

### Second Step

After the first modified layer 100 has been formed in the first wafer 10A in the first step, a ring-shaped second modified layer is formed in the first wafer 10A radially inwardly or outwardly of the first modified layer 100 at a relatively shallow position not reaching the interface 20 in the second step. In the second step according to the present embodiment, as illustrated in FIG. 6B, the laser beam LB is applied to the first wafer 10A while its focused spot is being positioned successively at respective positions spaced radially outwardly of and adjacent to the uppermost constituent layer, at the depth of 150 μm from the reverse side 10Ab, of the first modified layer 100 and the second uppermost constituent layer, at the depth of 160 μm from the reverse side 10Ab, of the first modified layer 100, and at the same time, the chuck table 34 is rotated about its vertical central axis, thereby forming second modified layers 102 and 104 in the first wafer 10A. Each of the second modified layers 102 and 104 should preferably be made up of a horizontal array of constituent layers, e.g., three constituent layers in the present embodiment, at the same depth from the reverse side 10Ab.

In the modified layer forming step, as described above, the first modified layer 100 is formed in the first wafer 10A in the first step, and the second modified layers 102 and 104 are then formed in the first wafer 10A at relatively shallow depthwise positions adjacent to the first modified layer 100 and not reaching the interface 20 in the second step. The second modified layers 102 and 104 thus formed apply stresses to the first modified layer 100, imparting an external force in a direction indicated by an arrow R3 to buckle the chamfered outer circumferential edge 17A away from the interface 20 along the first modified layer 100 that acts as a buckling initiating point. In this manner, the external force imparting step is carried out at the same time as the modified layer forming step. As a result, the bonding force in the bonding-force-reduced region 21 formed in the interface 20 is further reduced reliably, and the cracks formed along the first modified layer 100 are further developed.

The modified layer forming step is now completed. According to the embodiment described above, the second modified layers 102 and 104 are formed radially outwardly of and adjacent to the first modified layer 100. However, the present invention is not limited such details. Instead, the second modified layers 102 and 104 may be formed radially inwardly of and adjacent to the first modified layer 100. The second modified layers 102 and 104 thus formed radially inwardly of and adjacent to the first modified layer 100 are also effective to impart an external force in the direction indicated by the arrow R3 to buckle the chamfered outer circumferential edge 17A away from the interface 20 along the first modified layer 100 that acts as the buckling initiating point.

Each of the second modified layers 102 and 104 may not be made up of a horizontal array of three constituent layers, and may be made up of a horizontal array of two or less constituent layers or four or more constituent layers.

Laser processing conditions for carrying out the modified layer forming step are established as follows, for example:
Wavelength: 1099 nm
Repetitive frequency: 80 KHz
Average power output: 2.0 W
Processing feed speed: 450 mm/s
or
Wavelength: 1342 nm
Repetitive frequency: 90 kHz
Average power output: 1.9 W
Processing feed speed: 400 mm/s

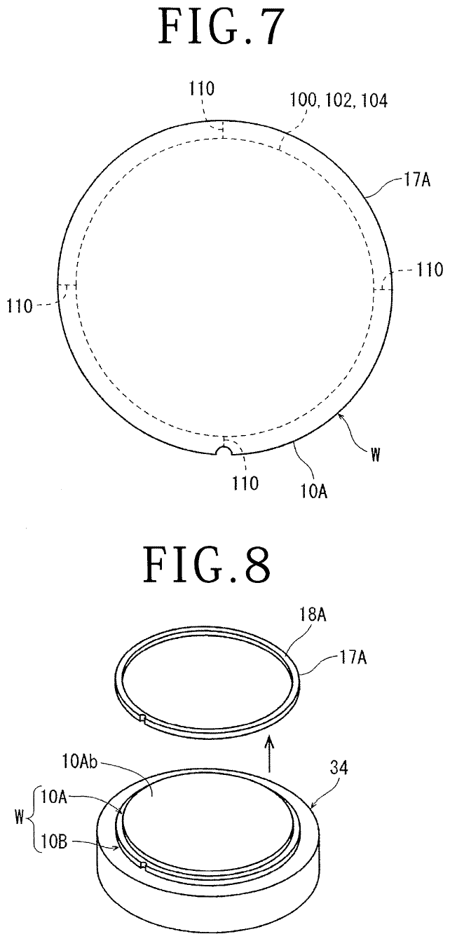

In the modified layer forming step, as illustrated in FIG. 7, radial modified layers 110 extending, radially outwardly toward the chamfered outer circumferential edge 17A, from the region where the first modified layer 100 or the second modified layers 102 and 104 are formed may be additionally formed in the first wafer 10A. The modified layers 110 function to divide the chamfered outer circumferential edge 17A into smaller fragments at the time when the chamfered outer circumferential edge 17A is removed. The modified layers 110 may be formed by the application of the laser beam LB to the first wafer 10A under the same laser processing conditions for forming the first modified layer 100. The modified layers 110 may be formed respectively in a plurality of locations, e.g., four locations in the present embodiment, that are angularly spaced at equal angular intervals along the outer circumferential portion of the first wafer 10A. When the chamfered outer circumferential edge 17A is to be removed subsequently in the chamfered outer circumferential edge removing step to be described below, the modified layers 110 divide the chamfered outer circumferential edge 17A into smaller fragments, allowing the chamfered outer circumferential edge 17A to be removed easily and effectively from the first wafer 10A.

After the chamfered outer circumferential edge removal promoting step and the modified layer forming step, the chamfered outer circumferential edge removing step is carried out to remove the chamfered outer circumferential edge 17A from the first wafer 10A, as illustrated in FIG. 8. According to the present embodiment, since the chamfered outer circumferential edge removal promoting step and the modified layer forming step have already been carried out, the bonding force of the interface 20 between the chamfered outer circumferential edge 17A of the first wafer 10A and the chamfered outer circumferential edge 17B of the second wafer 10B has been reduced, providing the ring-shaped bonding-force-reduced region 21. In addition, as the cracks have been formed along the first modified layer 100, the outer circumferential excess region 18A including the chamfered outer circumferential edge 17A can easily be dislodged and removed from the first wafer 10A along the first modified layer 100 acting as a removal initiating point. Any methods available in the art may be applied to carry out the chamfered outer circumferential edge removing step. For example, the nozzle 8a of the fluid supply unit 8 positioned sideways of the chuck table 34 may eject a stream of air or water to the interface 20, dislodging and removing the outer circumferential excess region 18A including the chamfered outer circumferential edge 17A from the first wafer 10A. At this time, the method of processing a wafer according to the present embodiment comes to an end. If the radial modified layers 110 have been formed in the first wafer 10A, then the chamfered outer circumferential edge 17A is removed as fragments in the chamfered outer circumferential edge removing step.

According to the embodiment described above, the chamfered outer circumferential edge removal promoting step is carried out prior to the modified layer forming step. The chamfered outer circumferential edge removal promoting step forms the ring-shaped bonding-force-reduced region 21 in the outer circumferential portion of the interface 20 of the bonded wafer assembly W, lowering the intimate contact between the first wafer 10A and the second wafer 10B in the bonding-force-reduced region 21, with the result that minuscule gaps are formed in the bonding-force-reduced region 21. As a result, even when the laser beam LB is applied to the first wafer 10A with its focused spot positioned relatively deeply in the first wafer 10A in the modified layer forming step, the laser beam LB applied to the first wafer 10A is prevented from adversely affecting the second wafer 10B and hence from causing damage to the second wafer 10B. Stated otherwise, the chamfered outer circumferential edge 17A can reliably be removed without using a cutting blade to cut and remove the chamfered outer circumferential edge 17A from the first wafer 10A, thereby freeing the second wafer 10B from damage caused by the use of such a cutting blade.

According to the above embodiment, the chamfered outer circumferential edge removal promoting step is carried out, and the modified layer forming step is thereafter carried out. In a case where the modified layer forming step is carried out as including the first step and the second step described with reference to FIGS. 6A and 6B, it is also effective to carry out the chamfered outer circumferential edge removal promoting step that supplies the fluid L for reducing the bonding force to the interface 20 after the modified layer forming step. Specifically, before the chamfered outer circumferential edge removal promoting step is carried out, the modified layer forming step including the first step and the second step is carried out, causing the second modified layers 102 and 104 formed in the second step to impart an external force for buckling the chamfered outer circumferential edge 17A from the interface 20 along the first modified layer 100 as the buckling initiating point. Thereafter, the chamfered outer circumferential edge removal promoting step is carried out to supply the fluid L for reducing the bonding force radially inwardly to the interface 20 that bonds the first wafer 10A and the second wafer 10B to each other. The application of the fluid L in combination with the external force imparted for buckling the chamfered outer circumferential edge 17A from the interface 20 in the modified layer forming step makes it possible to efficiently reduce the bonding force of the outer circumferential portion of the interface 20.

According to the present invention, the chamfered outer circumferential edge removal promoting step may be carried out at the same time as the modified layer forming step. Especially, since the laser processing apparatus 1 includes the fluid supply unit 8 disposed adjacent to the chuck table 34 of the holding unit 3, it is possible for the laser processing apparatus 1 to carry out the modified layer forming step simultaneously with the chamfered outer circumferential edge removal promoting step and to apply an external force to the interface 20 with the fluid L supplied from the fluid supply unit 8.

### First Modification

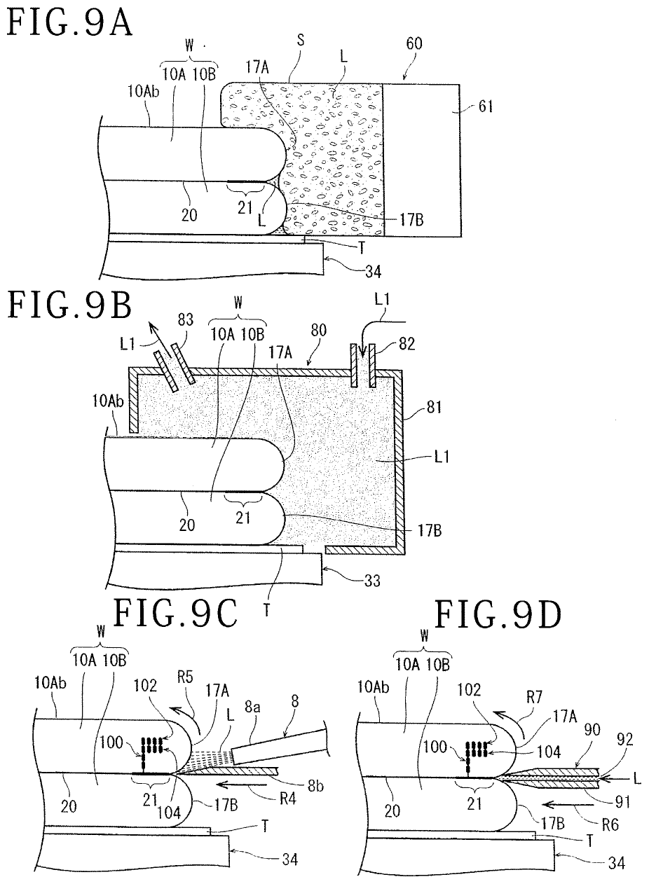

The chamfered outer circumferential edge removal promoting step is not limited to the details described in the above embodiment. FIG. 9A illustrates a first modification in which the chamfered outer circumferential edge removal promoting step is carried out by a fluid supply unit 60 including a sponge S that contains the fluid L, e.g., pure water, and a support base 61 that supports the sponge S. In operation, the sponge S that retains a sufficient amount of fluid L is pressed against an outer circumferential side edge of the bonded wafer assembly W held under suction on the chuck table 34 of the holding unit 3, supplying the interface 20 of the bonded wafer assembly W with the fluid L for reducing the bonding force of the interface 20. Then, the chuck table 34 is rotated about its vertical central axis to supply the fluid L to the entire outer circumferential side edge of the bonded wafer assembly W, sending water molecules gradually into a region of the interface 20 where the Si—O—Si bond changes into an Si—OH—OH—Si bond. In this manner, as with the fluid supply unit 8 according to the above embodiment, the fluid supply unit 60 can form the ring-shaped bonding-force-reduced region 21 for reducing the bonding force of the interface 20 to remove the chamfered outer circumferential edge 17A. The chamfered outer circumferential edge removal promoting step according to the first modification may be carried out before, after, or simultaneously with the modified layer forming step.

### Second Modification

FIG. 9B illustrates a second modification in which the chamfered outer circumferential edge removal promoting step is carried out by a fluid supply unit 80 that supplies water vapor or mist of atomized water as fluid L1. The fluid supply unit 80 includes a cover 81 for covering at least a portion of an outer circumferential portion of the bonded wafer assembly W. The cover 81 has a fluid inlet port 82 fluidly connected to an unillustrated fluid supply source that supplies the fluid L1 to the cover 81 and a fluid outlet port 83 fluidly connected to unillustrated fluid suction means that draws and drains the fluid L1 from within the cover 81. The fluid supply source may selectively be a vaporizer for producing water vapor by heating pure water or an ultrasonic vibrator for producing mist of pure water by ultrasonically vibrating pure water. The fluid L1 that has been supplied to the interior of the cover 81 from the fluid supply source is supplied to the entire outer circumferential side edge of the bonded wafer assembly W upon rotation of the chuck table 34 about its vertical central axis. The fluid L1 thus applied to the entire outer circumferential side edge of the bonded wafer assembly W sends water molecules gradually into a region of the interface 20 where the Si—O—Si bond changes into an Si—OH—OH—Si bond. As a result, as with the fluid supply unit 8 according to the above embodiment, the fluid supply unit 80 can form the ring-shaped bonding-force-reduced region 21 for reducing the bonding force of the interface 20 to remove the chamfered outer circumferential edge 17A. The fluid suction means draws and drains the fluid L1 from within the cover 81 through the fluid outlet port 83. The drained fluid L1 is retrieved by a suitable labyrinth mechanism, for example, so that the fluid L1 in the form of mist or vapor of water is prevented from leaking out of the cover 81. The chamfered outer circumferential edge removal promoting step according to the second modification may be carried out before, after, or simultaneously with the modified layer forming step, as with the first modification.

### Third Modification

FIG. 9C illustrates a third modification in which the fluid supply unit 8 for supplying the fluid L and a horizontal blade 8b are used to supply the fluid L to the interface 20 of the bonded wafer assembly W and to carry out the external force imparting step of imparting an external force for buckling the chamfered outer circumferential edge 17A from the interface 20 along the first modified layer 100 as the buckling initiating point. According to the illustrated third modification, after the modified layer forming step has been carried out in advance to form the first modified layer 100 and also the second modified layers 102 and 104, the horizontal blade 8b has its tip end advanced in a direction indicated by an arrow R4 toward the interface 20 laterally of the bonded wafer assembly W and the chuck table 34 is rotated about its vertical central axis, while, at the same time, the fluid L (pure water) is supplied from the nozzle 8a of the fluid supply unit 8 to an upper surface (or a lower surface) of the tip end of the horizontal blade 8b. As the fluid L is supplied to reduce the bonding force of the interface 20, the bonding force of the interface 20 is reduced to form the ring-shaped bonding-force-reduced region 21 in the interface 20, and the external force imparting step is carried out to buckle the chamfered outer circumferential edge 17A in a direction indicated by an arrow R5 from the interface 20 along the first modified layer 100 as the buckling initiating point. The chamfered outer circumferential edge removal promoting step according to the third modification may not be carried out after the modified layer forming step, and may be carried out at the same time as the modified layer forming step, i.e., may be carried out while the first modified layer 100 is being formed.

### Fourth Modification

FIG. 9D illustrates a fourth modification in which there is used a fluid supply unit 90 including a wedge member 91 that has a fluid passage 92 defined therein for supplying the fluid L therethrough to the tip end of the wedge member 91. According to the fourth modification, after the modified layer forming step has been carried out in advance to form the first modified layer 100 and also the second modified layers 102 and 104, the wedge member 91 has its tip end advanced in the direction indicated by an arrow R6 toward the interface 20 laterally of the bonded wafer assembly W and the chuck table 34 is rotated about its vertical central axis, while, at the same time, the fluid L for reducing the bonding force is supplied to the interface 20 through the fluid passage 92 to the tip end of the wedge member 91. According to the fourth modification, as with the third modification described above, the ring-shaped bonding-force-reduced region 21 is formed in the interface 20 to reduce the bonding force of the interface 20 by supplying the fluid L for reducing the bonding force to the interface 20, and the external force imparting step is carried out to buckle the chamfered outer circumferential edge 17A in a direction indicated by an arrow R7 from the interface 20 along the first modified layer 100 as the buckling initiating point. The chamfered outer circumferential edge removal promoting step according to the fourth modification may not be carried out after the modified layer forming step, and may be carried out at the same time as the modified layer forming step, i.e., may be carried out while the first modified layer 100 is being formed.

According to the present invention, in addition to the modified layer forming step, the chamfered outer circumferential edge removing step, and the chamfered outer circumferential edge removal promoting step described above, a grinding step may be carried out, if necessary, to grind the reverse side 10Ab of the first wafer 10A of the bonded wafer assembly W to process, i.e., thin down, the first wafer 10A to a desired thickness.

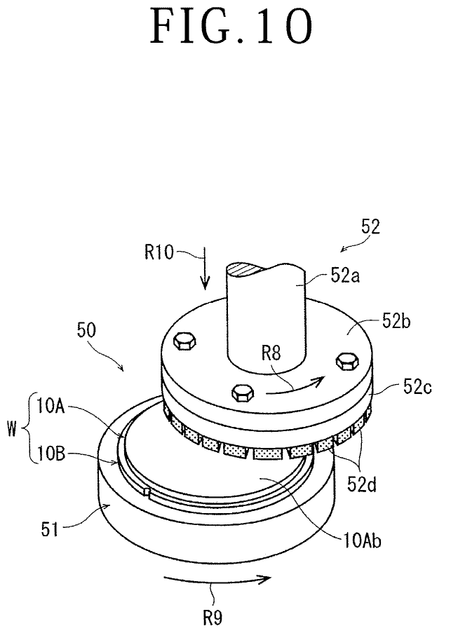

The grinding step will be described in detail below. The bonded wafer assembly W that has been subjected to the chamfered outer circumferential edge removing step is delivered to a grinding apparatus 50 that is only partly illustrated in FIG. 10. As illustrated in FIG. 10, the grinding apparatus 50 includes grinding means 52 for grinding and hence thinning down the bonded wafer assembly W held under suction on a chuck table 51. The grinding means 52 includes a rotary spindle 52a rotatable about its vertical central axis by an unillustrated rotating mechanism, a wheel mount 52b mounted on the lower end of the rotary spindle 52a, and a grinding wheel 52c attached to a lower surface of the wheel mount 52b. An annular array of grindstones 52d is disposed on a lower surface of the grinding wheel 52c.

After the bonded wafer assembly W has been delivered to the grinding apparatus 50, the bonded wafer assembly W with the second wafer 10B facing downwardly is placed on the chuck table 51, as depicted in FIG. 10, and held under suction on the chuck table 51 by unillustrated suction means. Next, the rotary spindle 52a of the grinding means 52 is rotated about its vertical central axis in a direction indicated by an arrow R8 at a speed of 6000 rpm, for example, while, at the same time, the chuck table 51 is rotated about its vertical central axis in a direction indicated by an arrow R9 at a speed of 300 rpm, for example. Then, an unillustrated grinding water supply unit supplies grinding water to the reverse side 10Ab of the first wafer 10A, and an unillustrated grinding feed mechanism is actuated to lower the rotary spindle 52a to bring the grindstones 52d into contact with the reverse side 10Ab of the first wafer 10A. Subsequently, the grinding feed mechanism grinding-feeds the grinding wheel 52c downwardly in a direction indicated by an arrow R10 at a grinding feed speed of 1.0 μm/s, for example, thereby grinding the reverse side 10Ab of the first wafer 10A. The reverse side 10Ab of the first wafer 10A is progressively ground by the grindstones 52d while, at the same time, the thickness of the bonded wafer assembly W is being measured by a contact-type or contactless-type thickness gauge, which is not illustrated, until the bonded wafer assembly W is thinned down to a desired thickness.

When the reverse side 10Ab of the first wafer 10A has been ground by a predetermined depth until the bonded wafer assembly W is thinned down to the desired thickness, the grinding means 52 is shut off and retracted, whereupon the grinding step is finished. Upon completion of the grinding step, a cleaning step and a drying step are appropriately carried out on the bonded wafer assembly W. The details of the cleaning step and the drying step are omitted from description.

The bonded wafer assembly W has been described above as including the first wafer 10A and the second wafer 10B that are bonded to each other by the siloxane bond. However, the first wafer 10A and the second wafer 10B may not be bonded together by the siloxane bond. For example, the first wafer 10A and the second wafer 10B may be bonded to each other by a SiCN bond as a nitride bond or a TEOS bond where tetraethyl orthosilicate molecules are changed to molecules having an Si—O—Si bond. Either bond has its bonding force reduced by the fluid L or the fluid L1. The present invention is also applicable to a bonded wafer assembly W having a bonding plane as the interface 20 that has been pretreated by O₂ plasma treatment or N₂ plasma treatment. The fluid L and the fluid L2 are not limited to pure water, and may be a mixture of pure water and another fluid containing water molecules.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A method of processing a wafer that is bonded as a first wafer to a second wafer in a bonded wafer assembly, comprising:
a modified layer forming step of applying a laser beam to the first wafer while positioning a focused spot of the laser beam within the first wafer radially inwardly of and adjacent to a chamfered outer circumferential edge of the first wafer, to form a ring-shaped modified layer in the first wafer;
a chamfered outer circumferential edge removal promoting step of supplying an interface between the first wafer and the second wafer that are bonded to each other near the chamfered outer circumferential edge with fluid for reducing a bonding force of the interface and sending the fluid into a region of the interface for removing the chamfered outer circumferential edge; and
after the chamfered outer circumferential edge removal promoting step, a chamfered outer circumferential edge removing step of removing the chamfered outer circumferential edge from the first wafer along the modified layer as a removal initiating point.

2. The method of processing a wafer according to claim 1, further comprising:
an external force imparting step of imparting an external force to the interface,
wherein the chamfered outer circumferential edge removal promoting step includes reducing the bonding force of the interface with the fluid in combination with the external force.

3. The method of processing a wafer according to claim 2,
wherein the modified layer forming step includes
a first step of applying the laser beam to the first wafer while positioning the focused spot thereof in a vicinity of the interface, to form a relatively deep first modified layer in the first wafer with cracks therealong reaching the interface, and
a second step of forming a relatively shallow second modified layer that is disposed radially inwardly or outwardly of and adjacent to the first modified layer and that does not reach the interface, and
the second step is carried out to impart an external force for buckling the chamfered outer circumferential edge away from the interface along the first modified layer as a buckling initiating point.

4. The method of processing a wafer according to claim 1, wherein the modified layer forming step includes forming a plurality of radial modified layers in the first wafer, the plurality of radial modified layers extending radially outwardly from the ring-shaped modified layer.

5. The method of processing a wafer according to claim 1, wherein the chamfered outer circumferential edge removal promoting step is carried out before the modified layer forming step, after the modified layer forming step, or simultaneously with the modified layer forming step.

6. The method of processing a wafer according to claim 1, further comprising:
after the chamfered outer circumferential edge removing step, a grinding step of grinding an upper surface of the first wafer to thin down the first water.

7. The method of processing a wafer according to claim 1,
wherein the first wafer and the second wafer are bonded to each other by a siloxane bond represented by an Si—O—Si bond, and the fluid for reducing the bonding force includes either water, water vapor, or water mist, and
the chamfered outer circumferential edge removal promoting step includes reducing the bonding force of the interface by changing the Si—O—Si bond to an Si—OH—OH—Si bond.
